(19) United States
(12) Patent Application Publication
(10) Pub. No.: US 2026/0053045 A1
(43) Pub. Date: Feb. 19, 2026

(54) INTEGRATED ENCAPSULATION DEPOSITION WITH METAL RECOVERY AND PASSIVATION

(71) Applicant: Applied Materials, Inc., Santa Clara, CA (US)

(72) Inventors: Jongbeom SEO, Santa Clara, CA (US); Devika GRANT, Santa Clara, CA (US); Zhijun CHEN, San Jose, CA (US); Fredrick FISHBURN, Aptos, CA (US); Raghuveer Satya MAKALA, Sunnyvale, CA (US)

(21) Appl. No.: 18/807,822

(22) Filed: Aug. 16, 2024

(51) Int. Cl. H01L 21/56; H01L 21/02; H01L 21/321; H01L 21/324; H01L 21/67

(52) U.S. Cl. CPC H01L 21/56; H01L 21/0234; H01L 21/321; H01L 21/324; H01L 21/67207

(57) ABSTRACT

A method of processing a metal layer for a semiconductor structure includes performing a metal surface recovery process to remove an oxidized or nitridized layer from a surface of the metal layer and recover a metal surface of the metal layer, performing a metal passivation process to passivate the metal surface of the metal layer and form a passivation layer, and performing an encapsulation layer deposition process to deposit an encapsulation layer on the passivation layer.

### BACKGROUND

### Field

Embodiments described herein generally relate to semiconductor device fabrication, and more particularly, to encapsulation of thin metal layers and features in dynamic random-access memory (DRAM) devices and NAND devices.

### Description of the Related Art

Dynamic random-access memory (DRAM) devices and NAND devices pose challenges in manufacturability due to their designs and small sizes. In such devices, metal layers and features, including buried word-line (bWL) in 6F² dynamic random-access memory (DRAM) devices, full fill or sheet word-lines (WLs) for 4F₂ DRAM, WLs for three dimensional (3D) DRAM, bit-lines (BL) for 6F² or 4F² DRAM, and WL for 3D NAND devices, also shrink from bulk dimension to less than 10 nm thickness.

For example, in DRAM devices, a bitline with low resistance is pursued to maximize the sense signal margin and thus molybdenum (Mo) has been used to form bitlines in DRAM devices due to its intrinsic low resistivity property. However, molybdenum (Mo) may be easily oxidized or nitridized during a DRAM device integration process and thus the low resistivity property may be degraded.

Therefore, there is a need for recovering lost cross-section in thin metal layers and features due to oxidation and nitridation and forming an effective low resistivity passivation layer to protect the thin metal layers and features from further oxidation and nitridation, before encapsulating the thin metal layers and feature.

### SUMMARY

Embodiments of the present disclosure provide a method of processing a metal layer for a semiconductor structure. The method includes performing a metal surface recovery process to remove an oxidized or nitridized layer from a surface of the metal layer and recover a metal surface of the metal layer, performing a metal passivation process to passivate the metal surface of the metal layer and form a passivation layer, and performing an encapsulation layer deposition process to deposit an encapsulation layer on the passivation layer.

Embodiments of the present disclosure also provide a method of processing a metal layer for a semiconductor structure. The method includes performing a metal surface recovery process to remove an oxidized or nitridized layer from a surface of a metal layer and recover a metal surface of the metal layer, performing a metal passivation process to passivate the metal surface of the metal layer and form a passivation layer, performing a first anneal process to stabilize the passivation layer, performing an encapsulation layer deposition process to deposit an encapsulation layer on the passivation layer, and performing a second anneal process to recover the metal layer.

Embodiments of the present disclosure further provide a multi-chamber cluster tool. The multi-chamber cluster tool includes a first processing chamber, a second processing chamber, a third processing chamber, and a controller configured to cause the multi-chamber cluster tool to perform, in the first processing chamber, a metal surface recovery process to remove an oxidized or nitridized layer from a surface of a metal layer and recover a metal surface of the metal layer, perform, in the second processing chamber, a metal passivation process to passivate the metal surface of the metal layer and form a passivation layer, and perform, in the third processing chamber, an encapsulation layer deposition process to deposit an encapsulation layer on the passivation layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 is a schematic top view of a multi-chamber processing system, according to one or more embodiments of the present disclosure.

FIG. 2 depicts a process flow diagram of a method of a device integration process forming a dielectric encapsulation on a metal layer in a semiconductor structure according to one embodiment.

FIGS. 3A, 3A′, 3A″, 3B, 3B′, 3B″, 3C, 3C′, 3C″, 3D, 3D′, and 3D″ are cross-sectional views of a portion of a semiconductor structure corresponding to various states of the method of FIG. 2.

To facilitate understanding, identical reference numerals have been used, where possible, to designate identical elements that are common to the figures. It is contemplated that elements and features of one embodiment may be beneficially incorporated in other embodiments without further recitation. In the figures and the following description, an orthogonal coordinate system including an X-axis, a Y-axis, and a Z-axis is used. The directions represented by the arrows in the drawings are assumed to be positive directions for convenience. It is contemplated that elements disclosed in some embodiments may be beneficially utilized on other implementations without specific recitation.

### DETAILED DESCRIPTION

The embodiments described herein provide methods and systems for a DRAM/NAND device integration process, in which thin metal layers and features are treated to recover oxidized or nitridized metal surface using reducing environment. The recovered metal surface is then passivated to protect the exposed surfaces from further oxidation or nitridation. The thin metal layers and features are then encapsulated, for example, by atomic layer deposition (ALD), as needed. An optional anneal step may be applied to promote grain growth and help stabilize the passivation layer. An additional optional anneal step may be applied to remove foreign/undesired elements introduced during passivation and return the metal to its pure and lowest resistivity state. The processes can be performed in a stand-alone chamber or on a multi-chamber system configured as part of a cluster.

Thin metal layers and features formed according to the embodiments described herein can have low metal resistance that can contribute a low capacitance, and thus, for example, bitlines lead to a better sensing signal performance in a DRAM device and metal interconnections provide low RC time delay.

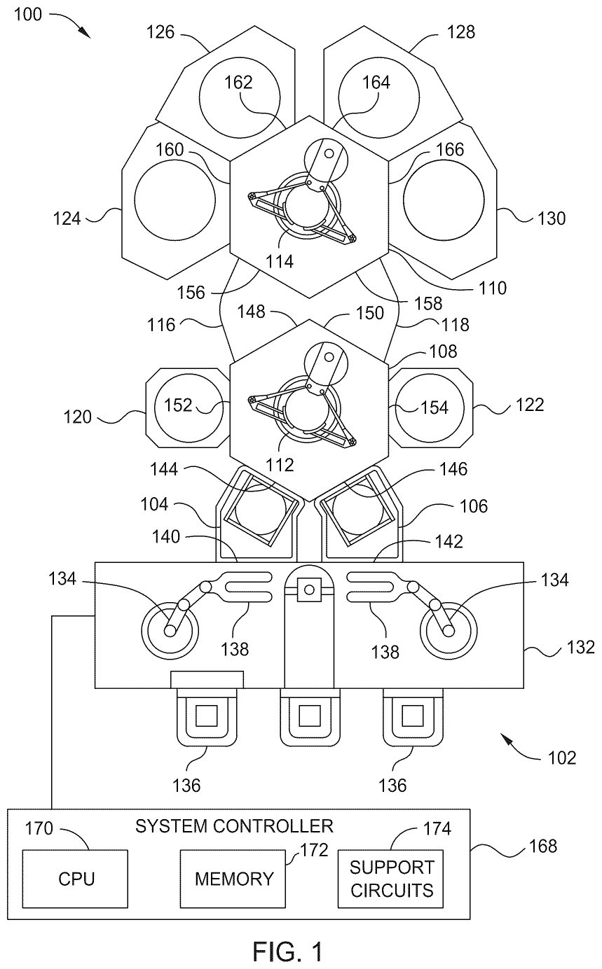

FIG. 1 is a schematic top view of a multi-chamber cluster tool 100, according to one or more embodiments of the present disclosure. The multi-chamber cluster tool 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the multi-chamber cluster tool 100 can be processed in and transferred between the various chambers without exposing the substrates to an ambient environment exterior to the multi-chamber cluster tool 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the multi-chamber cluster tool 100. Accordingly, the multi-chamber cluster tool 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

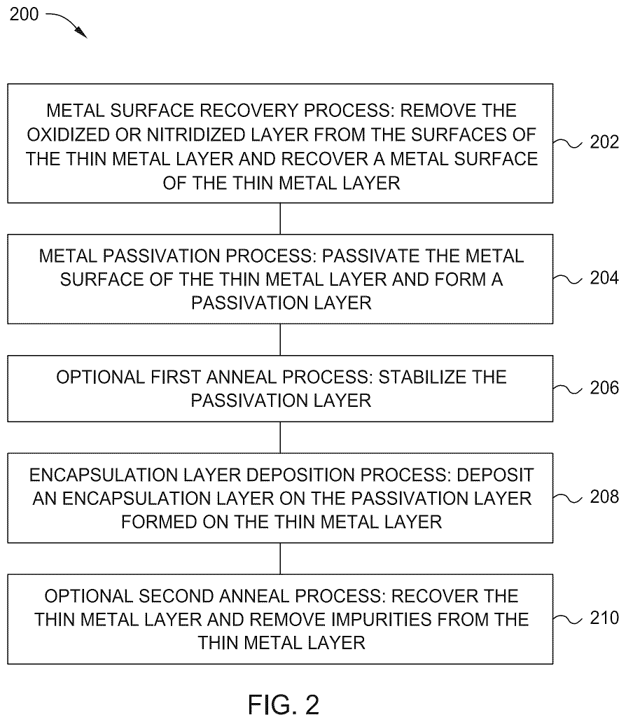

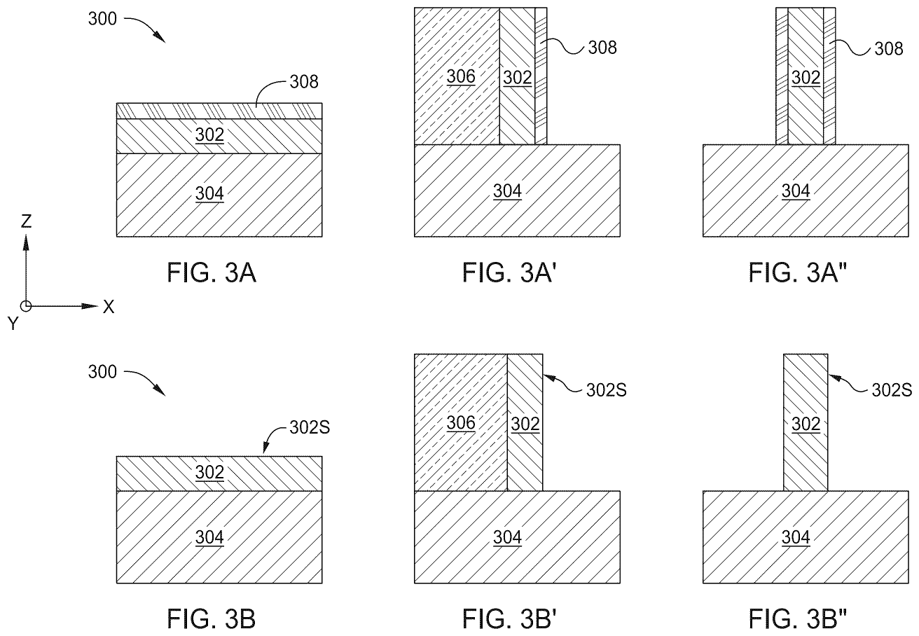

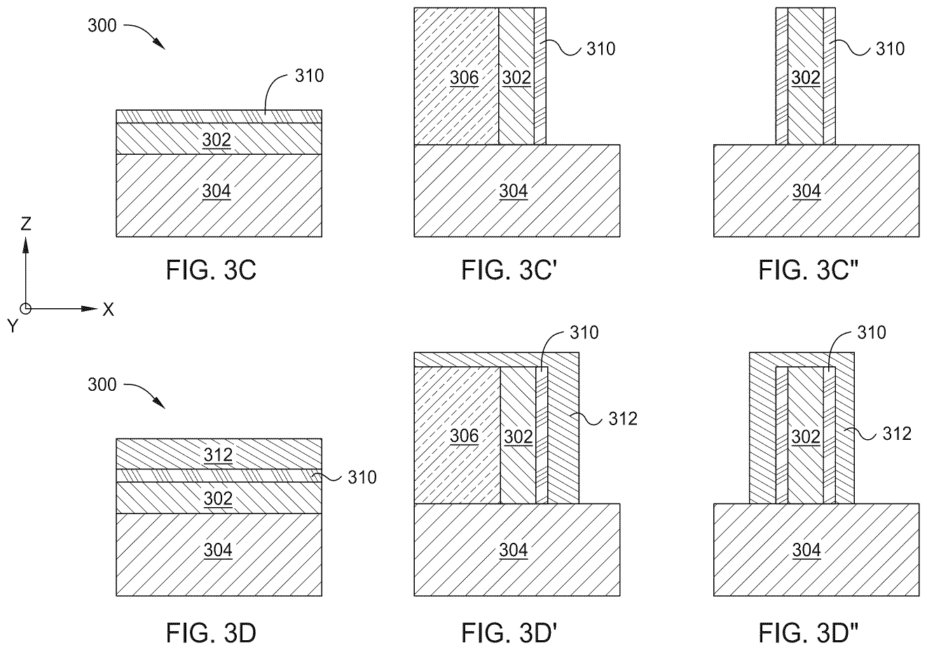

The processing chambers 120, 122, 124, 126, 128, 130 can be any appropriate chamber for processing a substrate. In some examples, the processing chamber 120 can be capable of performing an etch process, the processing chamber 122 can be capable of performing a cleaning process, and the processing chambers 126, 128, 130 can be capable of performing respective epitaxial growth processes. The processing chamber 120 may be a Selectra™ Etch chamber available from Applied Materials of Santa Clara, Calif. The processing chamber 122 may be an Aktiv™ Pre-clean (APC) chamber, a Pre-clean XT (MCxT-2) chamber, or a SiCoNi™ Pre-clean chamber, available from Applied Materials of Santa Clara, Calif. The processing chamber 124, 126, 128, or 130 may be a Centura™ Epi chamber, a Volta™ CVD/ALD chamber, an Encore™ PVD chamber, a selective tungsten deposition chamber, an ionized metal plasma physical vapor deposition (IMP PVD) chamber, a rapid thermal process (RTP) chamber, or a plasma etch (PE) chamber, available from Applied Materials of Santa Clara, Calif. A system controller 168 is coupled to the multi-chamber cluster tool 100 for controlling the multi-chamber cluster tool 100 or components thereof. For example, the system controller 168 may control the operation of the multi-chamber cluster tool 100 using a direct control of the chambers 104, 106, 108, 110, 116, 118, 120, 122, 124, 126, 128, 130 of the multi-chamber cluster tool 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the multi-chamber cluster tool 100. The system controller 168 is configured to cause the chambers 104, 106, 108, 110, 116, 118, 120, 122, 124, 126, 128, 130 of the multi-chamber cluster tool 100 to perform all of the operations described with respect to FIGS. 2, 3A, 3A′, 3A″, 3B, 3B′, 3B″, 3C, 3C′, 3C″, 3D, 3D′, and 3D″.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

FIG. 2 depicts a process flow diagram of a method 200 of a device integration process processing a metal layers for a semiconductor structure 300. FIGS. 3A, 3A′, 3A″, 3B, 3B′, 3B″, 3C, 3C′, 3C″, 3D, 3D′, and 3D″ are cross-sectional views of a portion of the semiconductor structure 300 corresponding to various states of the method 200. It should be understood that FIGS. 3A, 3A′, 3A″, 3B, 3B′, 3B″, 3C, 3C′, 3C″, 3D, 3D′, and 3D″ illustrate only partial schematic views of the semiconductor structure 300, and the semiconductor structure 300 may contain any number of transistor sections and additional materials having aspects as illustrated in the figures. It should also be noted that although the method illustrated in FIG. 2 is described sequentially, other process sequences that include one or more operations that have been omitted and/or added, and/or has been rearranged in another desirable order, fall within the scope of the embodiments of the disclosure provided herein.

As shown in FIGS. 3A, 3A′, and 3A″, the semiconductor structure 300 includes a thin metal layer 302 deposited on a surface of a substrate 304 (FIG. 3A), deposited on a sidewall of a feature 306 (FIG. 3A′), or etched to a stand-alone metal layer (FIG. 3A″). The thin metal layer 302 may be formed of molybdenum (Mo), tungsten (W), ruthenium (Ru), titanium (Ti), cobalt (Co), nickel (Ni), indium (Ir), rhodium (Rh), or a nitride thereof. During the fabrication processes (e.g., deposition or etch process to form the thin metal layer 302), exposed surfaces of the thin metal layer 302 may be oxidized or nitridized to form an oxidized or nitridized layer 308.

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polycrystalline silicon, doped or undoped silicon wafers and patterned or non-patterned wafers, silicon on insulator (SOI), carbon doped silicon oxides, silicon nitride, doped silicon, germanium, gallium arsenide, glass, or sapphire.

The method 200 begins with block 202, in which a metal surface recovery process is performed to remove the oxidized or nitridized layer 308 from the surfaces of the thin metal layer 302 and recover a metal surface 302S of the thin metal layer 302, as shown in FIGS. 3B, 3B′, and 3B″.

The metal surface recovery process may include a plasma treatment process in a continuous mode or a pulsed mode, performed in a pre-clean chamber, such as the processing chamber 122 shown in FIG. 1. In the plasma treatment process, the surfaces of the thin metal layer 302 are exposed to a plasma formed from a process gas including hydrogen (H₂), nitrogen (N₂), a mixture of hydrogen (H₂) and nitrogen (N₂), a mixture of hydrogen (H₂) and methane (CH₄), a mixture of hydrogen (H₂) and noble gas (e.g., helium (He), argon (Ar)), carbon oxide (CO), ammonia (NH₃), or any combination thereof. The plasma treatment process may be a radical-based pre-cleaning technique using a remote plasma assisted process in a continuous mode or a pulsed mode. The plasma treatment process may be a capacitively coupled plasma (CCP) process or Inductive coupled plasma process (ICP). The plasma treatment process may be performed at a temperature of between about 300° C. and about 650° C. for a duration of between about 10 seconds and about 3600 seconds.

The metal surface recovery process may include a thermal anneal process in reducing environment that includes carbon oxide (CO), nitrogen (N₂), hydrocarbons (CₓH_{y}) (e.g., methane (CH₄), ethane (C₂H₆), propane (C₃H₈), butane (C₄H₁₀), pentane (C₅H₁₂), hexane (C₆H₁₄)), hydrogen (H₂), ammonia (NH₃), a mixture thereof, and inert gas (e.g., helium (He), argon (Ar)) and other noble gas, performed in a rapid thermal processing (RTP) chamber, such as the processing chamber 120, 122, 124, 126, 128, or 130 shown in FIG. 1. The thermal anneal process may be performed for between about 10 second and about 3600 seconds, at a temperature of between about 300° C. and about 650° C., and at a pressure of between about 1 Torr and 100 Torr.

The high-pressure thermal anneal process may be used for metal recovery process. That process may be including hydrogen (H₂), deuterium (D₂), nitrogen (N₂), noble gas (e.g., helium (He), argon (Ar)), and a mixture thereof. The high-pressure thermal anneal process may be performed for between about 1 second and about 1 hour, at a temperature of less than 450° C., and at a pressure of between about 1 atm and 5 atm.

In block 204, a metal passivation process is performed to passivate the metal surface 302S of the thin metal layer 302 and form a passivation layer 310, as shown in FIGS. 3C, 3C′, and 3C″.

The passivation layer 310 may be formed of material having low resistivity, such as silicide of the thin metal layer 302 (e.g., molybdenum silicide (MoSi₂), tungsten silicide (WSi₂), ruthenium silicide (Ru₂Si₃), titanium silicide (TiSi₂), cobalt silicide (CoSi₂), nickel silicide (Ni₂Si), indium silicide (IrSi), rhodium silicide (RhSi)), boride of the thin metal layer 302 (e.g., molybdenum boride (MoB), tungsten boride (WB), ruthenium boride (RuB₂, Ru₂B₃), titanium boride (TiB₂), cobalt boride (CoB₂), nickel boride (Ni₂B), indium boride (IrB₃), rhodium boride (RhB)), or carbide of the thin metal layer 302 (e.g., molybdenum carbide (Mo₂C), tungsten carbide (WC), ruthenium carbide (RuC), titanium carbide (TIC), cobalt carbide (Co₂C), nickel carbide (NiC), indium carbide (IrC), rhodium carbide (RhC)).

The passivation layer 310 may suppress diffusion of oxygen or nitrogen into the thin metal layer 302 during subsequent material deposition thereon, and thus protect the thin metal layer 302 from oxidation or nitridation until the end of the device integration process.

The metal passivation process may be a plasma process, a radical-based plasma process, a soaking process, or a combination of a deposition process and a thermal anneal process in a continuous mode or a pulsed mode, performed in a thermal processing chamber, a plasma chamber, a radical chamber, or an ALD chamber, such as the processing chamber 124, 126, 128, or 130 shown in FIG. 1. In the metal passivation process, the semiconductor structure 300 is exposed to a gas precursor including silicon (Si)/germanium (Ge) and hydrogen (H₂) compounds, such as silane (SiH₄), disilane (Si₂H₆), and trisilane (Si₃H₈), or silicon (Si) and halogen compounds, such as silicon tetrafluoride (SiF₄), silicon tetrachloride (SiCl₄), germane (GeH₄), and silicon tetrabromide (SiBr₄), silicon (Si), hydrogen (H₂), halogen compounds, such as dichlorosilane (H₂SiCl₂, DCS), trichlorosilane (HCl₃Si), methylsilane (H₃CSiH₃), or other hydrogen (H₂) compounds, such as phosphine (PH₃), diborane (B₂H₆), arsine (AsH₃), and trimethylamine (TMA, N(CH₃)₃)), to form the passivation layer 310 of metal silicide (e.g., molybdenum silicide (MoSi₂), tungsten silicide (WSi₂), ruthenium silicide (Ru₂Si₃), titanium silicide (TiSi₂), cobalt silicide (CoSi₂), nickel silicide (Ni₂Si), indium silicide (IrSi), rhodium silicide (RhSi)). The carrier gas may include nitrogen (N₂), hydrogen (H₂), and noble gas (e.g., helium (He), argon (Ar)).

In some embodiments, the gas precursor includes boron and hydrogen compounds, such as borane (BH₃), diborane (B₂H₆), or boron and halogen compounds, such as boron trifluoride (BF₃), boron trichloride (BCl₃), and boron tribromide (BBr₃), to form the passivation layer 310 of metal boride (e.g., molybdenum boride (MoB), tungsten boride (WB), ruthenium boride (RuB₂, Ru₂B₃), titanium boride (TiB₂), cobalt boride (CoB₂), nickel boride (Ni₂B), indium boride (IrB₃), rhodium boride (RhB)).

In some embodiments, the gas precursor includes carbon and hydrogen compounds, such as self-assembled monolayer (SAM) organic molecules (e.g., methane (CH₄), trimethylamine (TMA, N(CH₃) 3)), to form the passivation layer 310 of metal carbide (e.g., molybdenum carbide (Mo₂C), tungsten carbide (WC), ruthenium carbide (RuC), titanium carbide (TIC), cobalt carbide (Co₂C), nickel carbide (NiC), indium carbide (IrC), rhodium carbide (RhC)).

The plasma-assisted metal passivation process may be performed at a temperature of between about 300° C. and about 650° C. for a duration of between about 10 seconds and about 3600 seconds.

In some embodiments, the metal passivation process includes a deposition process, such as chemical vapor deposition (CVD), atomic layer deposition (ALD), or the like, performed in a processing chamber, such as the processing chamber 126, 128, or 130 shown in FIG. 1, followed by a thermal anneal process performed in a rapid thermal processing (RTP) chamber, such as the processing chamber 120, 122, 124, 126, 128, or 130 shown in FIG. 1. The thermal anneal process may be performed for between about 10 second and about 300 seconds, at a temperature of between about 300° C. and about 650° C., and at a pressure of between about 1 Torr and 760 Torr.

In block 206, an optional first anneal process is performed to stabilize the passivation layer 310. In some embodiments, the thin metal layer 302 (e.g., molybdenum (Mo)) and the passivation layer 310 (e.g., molybdenum silicide (MoSi₂)) are partially merged and stabilized by the optional first anneal process.

The optional first anneal process may be performed for between about 10 second and about 3600 seconds, at a temperature of between about 100° C. and about 650° C., and at a pressure of between about 1 Torr and 760 Torr.

In block 208, an encapsulation layer deposition process is performed to deposit an encapsulation layer 312 on the passivation layer 310 formed on the thin metal layer 302, as shown in FIGS. 3D, 3D′, and 3D″.

The encapsulation layer 312 may be formed of a self-assembled monolayer (SAM) of organic molecules, such as methane (CH₄), or a thin layer of dielectric material, such as silicon dioxide (SiO₂), silicon nitride (Si₃N₄), silicon carbonitride (SiCN), silicon boron nitride (SiBN), silicon oxycarbide (SiOC), or silicon oxynitride (SiON), or a combination thereof. The encapsulation layer 312 is a conformal and ultra-thin layer, having a thickness of less than about 30 Å.

The encapsulation layer deposition process may be an ALD process, a CVD soaking process, a plasma process, or a radical-based plasma process, or, performed in an ALD chamber, a CVD chamber, a thermal processing chamber, a plasma chamber, or a radical chamber, such as the processing chamber 124, 126, 128, or 130 shown in FIG. 1. In some embodiments, the encapsulation layer deposition process in block 208 is the same as the plasma treatment process in block 202. The metal surface recovery process in block 202, the metal passivation process in block 204, the optional first anneal process in block 206, the encapsulation layer deposition process in block 208, and the optional second anneal process in block 210 may be performed in a multi-chamber cluster tool, such as the multi-chamber cluster tool 100, shown in FIG. 1, without vacuum break.

In some embodiments, the metal surface recovery process in block 202, the metal passivation process in block 204, and a CVD process as the encapsulation layer deposition process in block 208 may be performed in a CVD chamber, such as the processing chamber 124, 126, 128, or 130 shown in FIG. 1. The metal surface recovery process in block 202 and the metal passivation process in block 204 may be performed in a continuous mode.

In some embodiments, the metal surface recovery process in block 202, the metal passivation process in block 204, and an ALD process as the encapsulation layer deposition process in block 208 may be performed in an ALD chamber, such as the processing chamber 124, 126, 128, or 130 shown in FIG. 1. The metal surface recovery process in block 202 and the metal passivation process in block 204 may be performed in a continuous mode or a pulsed mode.

In the encapsulation layer deposition process, the surface of the semiconductor structure 300 (e.g., the passivation layer 310) is exposed to a gas precursor including an unsaturated hydrocarbon, at a temperature of less than about 450° C. and a pressure of less than about 100 Torr for a duration of greater than about 10 seconds, with a flow rate of the precursor of between 10 sccm and about 600 sccm. In some embodiments, a liquid precursor is used in the soaking process.

In block 210, in the embodiments in which the optional first anneal process in block 206 is performed, an optional second anneal process is performed to recover the thin metal layer 302 (e.g., molybdenum (Mo)) and remove impurities from the thin metal layer 302. The partially merged thin metal layer 302 (e.g., molybdenum (Mo)) and the passivation layer 310 (e.g., molybdenum silicide (MoSi₂)) are returned to thin metal layer 302 (e.g., molybdenum (Mo)) by the optional second anneal process.

The optional second anneal process may be performed for between about 10 second and about 3600 seconds, at a temperature of between about 100° C. and about 650° C., and at a pressure of between about 1 Torr and 760 Torr.

The embodiments described herein provide methods and systems for a DRAM/NAND device integration process, in which thin metals and features are treated to recover oxidized or nitridized metal surface using reducing environment, the recovered metal surface is passivated to protect the exposed surfaces from further oxidation or nitridation, and then the thin metals and features are encapsulated, for example, by atomic layer deposition (ALD), as needed. An optional anneal step may be applied to promote grain growth and help stabilize the passivation layer. An additional optional anneal step may be applied to remove foreign/undesired elements introduced during passivation and return the metal to its pure and lowest resistivity state. The processes can be performed in a stand-alone chamber or on a multi-chamber system configured as part of a cluster.

While the foregoing is directed to embodiments of the present disclosure, other and further embodiments of the disclosure may be devised without departing from the basic scope thereof, and the scope thereof is determined by the claims that follow.

1. A method of processing a metal layer for a semiconductor structure, comprising:
performing a metal surface recovery process to remove an oxidized or nitridized layer from a surface of the metal layer and recover a metal surface of the metal layer;
performing a metal passivation process to passivate the metal surface of the metal layer and form a passivation layer; and
performing an encapsulation layer deposition process to deposit an encapsulation layer on the passivation layer.

2. The method of claim 1, wherein the metal surface recovery process, the metal passivation process, and the encapsulation layer deposition process are performed without breaking vacuum.

3. The method of claim 1, wherein the metal surface recovery process comprises exposing the surface of the metal layer to a plasma formed from a process gas including hydrogen (H₂), nitrogen (N₂), a mixture of hydrogen (H₂) and nitrogen (N₂), a mixture of hydrogen (H₂) and methane (CH₄), a mixture of hydrogen (H₂) and noble gas, carbon oxide (CO), ammonia (NH₃), or any combination thereof.

4. The method of claim 1, wherein the metal surface recovery process comprises a thermal anneal process in reducing environment that includes carbon oxide (CO), nitrogen (N₂), hydrocarbons (CₓH_{y}), hydrogen (H₂), ammonia (NH₃), or a mixture thereof.

5. The method of claim 1, wherein:
the metal layer comprises molybdenum (Mo), tungsten (W), ruthenium (Ru), titanium (Ti), cobalt (Co), nickel (Ni), indium (Ir), rhodium (Rh), or a nitride thereof,
the passivation layer comprises silicide, boride, or carbide of the metal layer, and
the metal passivation process comprises a plasma process, a radical-based plasma process, a soaking process, or a combination of a deposition process and a thermal anneal process.

6. The method of claim 1, wherein:
the encapsulation layer deposition process comprises soaking the passivation layer in a gas precursor including an unsaturated hydrocarbon, and
the encapsulation layer comprises a self-assembled monolayer (SAM) of organic molecules having a thickness of less than 30 Å.

7. The method of claim 1, wherein the encapsulation layer comprises silicon nitride (Si₃N₄), silicon dioxide (SiO₂), silicon oxynitride (SiON), silicon carbonitride (SiCN), or silicon oxycarbide (SiOC).

8. A method of processing a metal layer for a semiconductor structure, comprising:
performing a metal surface recovery process to remove an oxidized or nitridized layer from a surface of the metal layer and recover a metal surface of the metal layer;
performing a metal passivation process to passivate the metal surface of the metal layer and form a passivation layer;
performing a first anneal process to stabilize the passivation layer;
performing an encapsulation layer deposition process to deposit an encapsulation layer on the passivation layer; and
performing a second anneal process to recover the metal layer.

9. The method of claim 8, wherein the metal surface recovery process, the metal passivation process, and the encapsulation layer deposition process are performed without breaking vacuum.

10. The method of claim 8, wherein the metal surface recovery process comprises exposing the surface of the metal layer to a plasma formed from a process gas including hydrogen (H₂), nitrogen (N₂), a mixture of hydrogen (H₂) and nitrogen (N₂), a mixture of hydrogen (H₂) and methane (CH₄), a mixture of hydrogen (H₂) and noble gas, carbon oxide (CO), ammonia (NH₃), or any combination thereof.

11. The method of claim 8, wherein the metal surface recovery process comprises a thermal anneal process in reducing environment that includes carbon oxide (CO), nitrogen (N₂), hydrocarbons (CₓH_{y}), hydrogen (H₂), ammonia (NH₃), or a mixture thereof.

12. The method of claim 8, wherein:
the metal layer comprises molybdenum (Mo), tungsten (W), ruthenium (Ru), titanium (Ti), cobalt (Co), nickel (Ni), indium (Ir), rhodium (Rh), or a nitride thereof,
the passivation layer comprises silicide, boride, or carbide of the metal layer, and
the metal passivation process comprises a plasma process, a radical-based plasma process, a soaking process, or a combination of a deposition process and a thermal anneal process.

13. The method of claim 8, wherein:
the encapsulation layer deposition process comprises soaking the passivation layer in a gas precursor including an unsaturated hydrocarbon, and
the encapsulation layer comprises a self-assembled monolayer (SAM) of organic molecules having a thickness of less than 30 Å.

14. The method of claim 8, wherein the encapsulation layer comprises silicon nitride (Si₃N₄), silicon dioxide (SiO₂), silicon oxynitride (SiON), silicon carbonitride (SiCN), or silicon oxycarbide (SiOC).

15. A multi-chamber cluster tool comprising:
a first processing chamber;
a second processing chamber;
a third processing chamber; and
a controller configured to cause the multi-chamber cluster tool to:
perform, in the first processing chamber, a metal surface recovery process to remove an oxidized or nitridized layer from a surface of a metal layer and recover a metal surface of the metal layer;
perform, in the second processing chamber, a metal passivation process to passivate the metal surface of the metal layer and form a passivation layer; and
perform, in the third processing chamber, an encapsulation layer deposition process to deposit an encapsulation layer on the passivation layer.

16. The multi-chamber cluster tool of claim 15, wherein the metal surface recovery process, the metal passivation process, and the encapsulation layer deposition process are performed without vacuum break.

17. The multi-chamber cluster tool of claim 15, further comprising:
a fourth processing chamber; and
a fifth processing chamber, wherein the controller is further configured to case the multi-chamber cluster tool to:
perform, in the fourth processing chamber, a first anneal process to stabilize the passivation layer, and
perform, in the fifth processing chamber, a second anneal process to recover the metal layer.

18. The multi-chamber cluster tool of claim 15, wherein:
the metal layer comprises molybdenum (Mo), tungsten (W), ruthenium (Ru), titanium (Ti), cobalt (Co), nickel (Ni), indium (Ir), rhodium (Rh), or a nitride thereof,
the metal surface recovery process comprises exposing the surface of the metal layer to a plasma formed from a process gas including hydrogen (H₂), nitrogen (N₂), a mixture of hydrogen (H₂) and nitrogen (N₂), a mixture of hydrogen (H₂) and methane (CH₄), a mixture of hydrogen (H₂) and noble gas, carbon oxide (CO), ammonia (NH₃), or any combination thereof, and
the metal surface recovery process comprises a thermal anneal process in reducing environment that includes carbon oxide (CO), nitrogen (N₂), hydrocarbons (CₓH_{y}), hydrogen (H₂), ammonia (NH₃), or a mixture thereof.

19. The multi-chamber cluster tool of claim 15, wherein:
the passivation layer comprises silicide, boride, or carbide of the metal layer, and
the metal passivation process comprises a plasma process, a radical-based plasma process, a soaking process, or a combination of a deposition process and a thermal anneal process.

20. The multi-chamber cluster tool of claim 15, wherein:
the encapsulation layer deposition process comprises soaking the passivation layer in a gas precursor including an unsaturated hydrocarbon,
the encapsulation layer comprises a self-assembled monolayer (SAM) of organic the encapsulation layer comprises silicon nitride (Si₃N₄), silicon dioxide (SiO₂), silicon oxynitride (SiON), silicon carbonitride (SiCN), or silicon oxycarbide (SiOC).
